(19) United States
(12) Patent Application Publication
(10) Pub. No.: US 2017/0089959 A1
(43) Pub. Date: Mar. 30, 2017

(54) INFORMATION PRESENTATION METHOD AND INFORMATION PRESENTATION DEVICE

(71) Applicant: Panasonic Intellectual Property Corporation of America, Torrance, CA (US)

(72) Inventors: HAYASHI ITO, Kanagawa (JP); TOMOAKI OHIRA, Tokyo (JP); KUMI HARADA, Osaka (JP)

(21) Appl. No.: 15/208,815

(22) Filed: Jul. 13, 2016

(30) Foreign Application Priority Data
Sep. 30, 2015 (JP) 2015-193869

(51) Int. Cl. G01R 21/133; G01R 22/06

(52) U.S. Cl. CPC G01R 21/1336; G01R 22/063

(57) ABSTRACT

An information presentation method includes: measuring a first consumption amount that is an amount of the energy actually consumed by a device installed in a section in a building; calculating a second consumption amount that is an amount of the energy assumed to be consumed by the device in order to maintain an environment value that indicates an environment of the section; generating difference information indicating a difference between the second consumption amount and the first consumption amount; outputting the difference information to a terminal; and causing the terminal to present the difference information.

### BACKGROUND

1. Technical Field

The present disclosure relates to an information presentation method and an information presentation device with which information relating to energy consumption is presented.

2. Description of the Related Art

Technology for displaying information relating to energy consumption (electricity, gas, or the like) on a predetermined terminal device in a residence or the like is conventionally known.

For example, International Publication No. 15/046320 discloses technology with which a person-detecting sensor installed in a predetermined room of a residence detects that persons are not present, and, in the case where power consumption by an electrical device installed in that room is detected, information indicating that power is being wasted is displayed.

### SUMMARY

The technology of International Publication No. 15/046320 is for notifying a resident of wasteful power usage, and, in the case where the resident has carried out an action that contributes to energy saving (an action that turns off an illumination device to let in natural light, for example), the power usage reduction effect obtained by that action is not notified to the resident.

One non-limiting and exemplary embodiment provides an information presentation method and an information presentation device with which a user can be notified of a power usage reduction effect obtained by the carrying out of an action that contributes to energy saving.

In one general aspect, the techniques disclosed here feature an information presentation method includes: measuring a first consumption amount that is an amount of the energy actually consumed by a device installed in a section in a building; calculating a second consumption amount that is an amount of the energy assumed to be consumed by the device in order to maintain an environment value that indicates an environment of the section; generating difference information indicating a difference between the second consumption amount and the first consumption amount; outputting the difference information to a terminal; and causing the terminal to present the difference information.

According to the present disclosure, a user can be notified of a power usage reduction effect obtained by the carrying out of an action that contributes to energy saving.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram depicting an example of the configuration of an information presentation system and an information presentation device according to an embodiment of the present disclosure;

FIG. 2 is a block diagram depicting an example of a configuration of a control unit of the information presentation device according to the embodiment of the present disclosure;

FIG. 3 is a drawing depicting an example of function data according to the embodiment of the present disclosure;

FIG. 4 is a drawing depicting an example of a table according to the embodiment of the present disclosure;

FIG. 5 is a flowchart depicting an example of the flow of information presentation processing according to the embodiment of the present disclosure;

FIG. 6 is a block diagram depicting an example of the configuration of an information presentation system and an information presentation device according to a modified example of the present disclosure;

FIG. 7 is a drawing depicting an example of function data according to the modified example of the present disclosure;

FIG. 8 is a drawing depicting an example of the hardware configuration of a computer that realizes the functions of a server and a terminal by means of software according to an embodiment of the present disclosure;

FIG. 9 is a drawing depicting service model 1 (type where a company itself serves as a data center);

FIG. 10 is a drawing depicting service model 2 (IaaS-utilizing type);

FIG. 11 is a drawing depicting service model 3 (PaaS-utilizing type); and

FIG. 12 is a drawing depicting service model 4 (SaaS-utilizing type).

### DETAILED DESCRIPTION

Hereinafter, an embodiment of the present disclosure will be described in detail with reference to the drawings. However, configurations and processing operations that are the same are denoted by the same reference numerals in the drawings used to describe the embodiments, and redundant descriptions thereof are omitted.

### <Configuration of Information Presentation System>

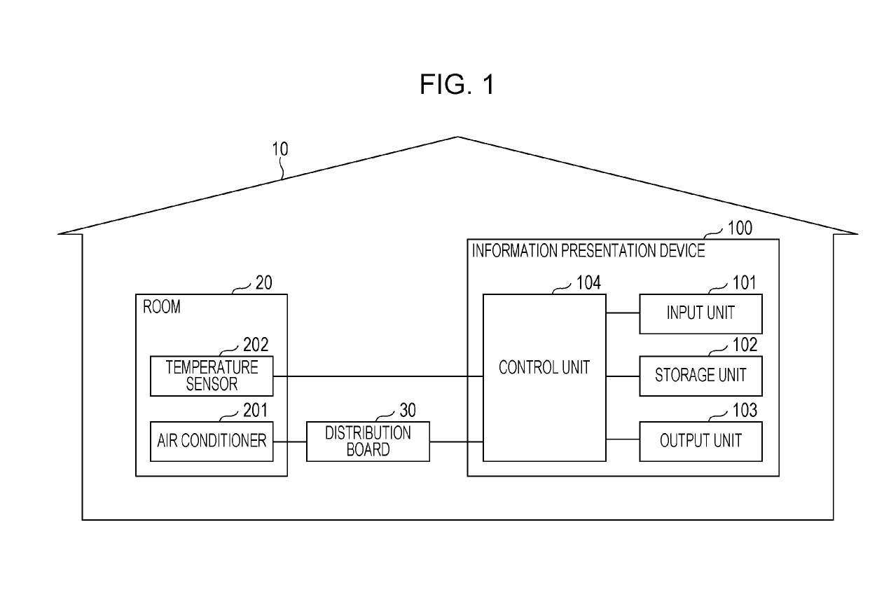

To begin, FIG. 1 will be used to describe the configuration of an information presentation system and an information presentation device according to an embodiment of the present disclosure. FIG. 1 is a block diagram depicting an example of the configuration of the information presentation system and the information presentation device according to the present embodiment.

As depicted in FIG. 1, the information presentation system of the present embodiment has, in a building 10, an air conditioner (air conditioner device) 201, a temperature sensor 202, a distribution board 30, and an information presentation device 100.

The building 10 is a detached residence, for example. It should be noted that the building 10 is not restricted to a detached residence, and, for example, may be one exclusively-owned dwelling in a residential complex, one office building, or one exclusively-owned section in an office building.

The building 10 has a room 20 (an example of a section). The room 20 has installed therein the air conditioner 201 (an example of a device), which operates by means of power supplied from the distribution board 30, and the temperature sensor 202 (an example of an environment sensor), which detects the temperature inside the room 20. It should be noted that the temperature sensor 202 may be able to measure not only the room temperature but also the sensory temperature.

Only the room 20 is depicted in FIG. 1, but it should be noted that there may be a plurality of rooms in the building 10. Furthermore, a device other than the air conditioner 201 (a device that is operated by means of power supplied from the distribution board 30; an electric fan, for example) may be installed in the room 20. Furthermore, the case where a room serves an example of a section in the building 10 is described as an example in the present embodiment; however, a section is not restricted to a room.

The air conditioner 201 is electrically connected to an input unit 101 of the information presentation device 100 by way of the distribution board 30. Furthermore, the temperature sensor 202 is electrically connected to the input unit 101 of the information presentation device 100.

The information presentation device 100 is, for example, a home energy management system (HEMS) that manages energy used in the residence. It should be noted that the case where the energy is constituted by electrical power is described as an example in the present embodiment.

As depicted in FIG. 1, the information presentation device 100 has the input unit 101, a storage unit 102, an output unit 103, and a control unit 104.

The input unit 101 is an input device such as a button or a touch panel.

For example, the input unit 101 receives a preset operation, an information output instruction operation, and the like. The preset operation is, for example, an operation with which a resident (an example of a user) of the building 10 designates the association between a room (the room 20, for example) in the building 10, a device (the air conditioner 201, for example) installed in that room, and an environment sensor (the temperature sensor 202, for example) installed in that room. The information output instruction operation is, for example, an operation with which the resident of the building 10 instructs difference information to be output. Details of the difference information will be described later on.

The storage unit 102 is a storage device such as a memory or a hard disk device.

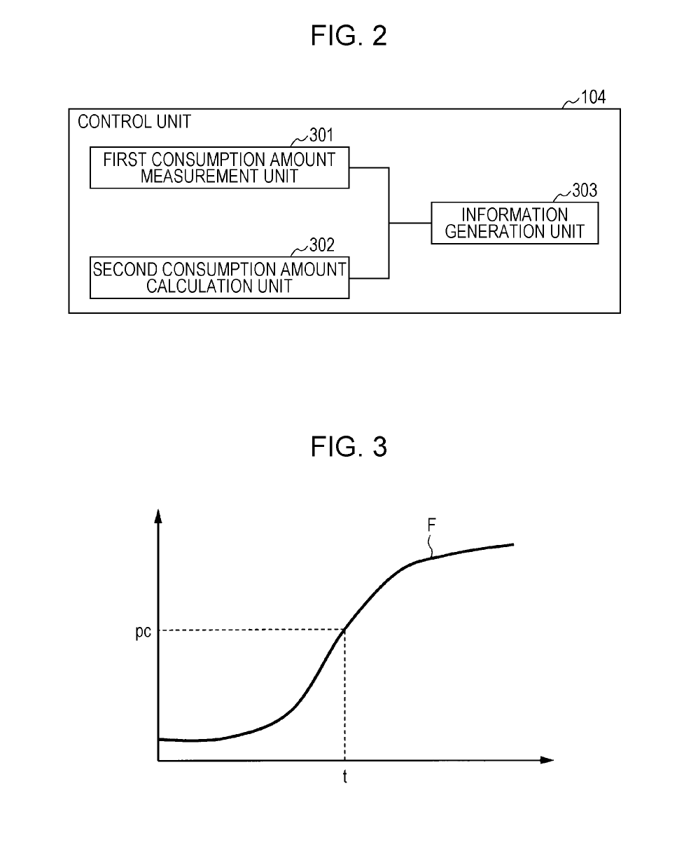

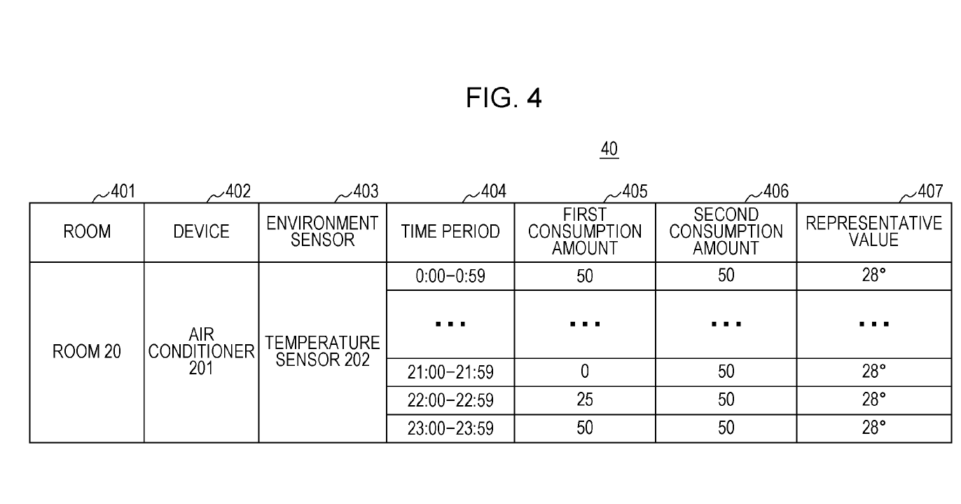

The storage unit 102 stores function data and a table, for example. Details of the function data will be described later on using FIG. 3, and details of the table will be described later on using FIG. 4.

The output unit 103 is a display device such as a display or an audio output device such as a speaker.

The output unit 103 displays the difference information, for example. It should be noted that the case where the difference information is output in a display form is described as an example in the present embodiment.

The control unit 104 is a control device such as a processor that executes various information processing.

As depicted in FIG. 2, the control unit 104 has a first consumption amount measurement unit 301, a second consumption amount calculation unit 302, and an information generation unit 303.

The first consumption amount measurement unit 301 acquires, by way of the distribution board 30, power data indicating a power amount actually consumed by the device (the air conditioner 201, for example) installed in the room 20. It should be noted that the first consumption amount measurement unit 301 may acquire the power data directly from the device without going through the distribution board 30.

The first consumption amount measurement unit 301 measures a power consumption amount (hereinafter referred to as a first consumption amount) in each predetermined time period (an example of a predetermined period; one hour, for example) on the basis of the acquired power data. The first consumption amount is the power amount actually consumed due to the operation of the device installed in the room 20.

It should be noted that in the case where an electric fan (not depicted) is installed as well as the air conditioner 201 in the room 20, the first consumption amount measurement unit 301 measures the first consumption amount on the basis of the power data of each of the air conditioner 201 and the electric fan. For example, in the case where the air conditioner 201 is operating and the electric fan is not operating in the predetermined time period, the first consumption amount measured is the power amount that is actually consumed due to the operation of the air conditioner 201. Furthermore, for example, in the case where the electric fan is operating and the air conditioner 201 is not operating in the predetermined time period, the first consumption amount measured is the power amount that is actually consumed due to the operation of the electric fan. Furthermore, for example, in the case where both the air conditioner 201 and the electric fan are operating in the predetermined time period, the first consumption amount measured is the total of the power amount that is actually consumed due to the operation of the air conditioner 201 and the power amount that is actually consumed due to the operation of the electric fan.

The second consumption amount calculation unit 302 acquires room temperature data indicating a value (an example of an environment value) for the room temperature of the room 20 detected by the temperature sensor 202. Furthermore, the second consumption amount calculation unit 302 reads out function data (see FIG. 3) from the storage unit 102.

The second consumption amount calculation unit 302 then calculates a power consumption amount (hereinafter referred to as a second consumption amount) in each predetermined time period (an example of the predetermined period; one hour, for example) on the basis of the room temperature data and the function data. The second consumption amount is the power amount assumed to be consumed by the air conditioner 201 in order to maintain the room temperature of the room temperature data.

Here, an example of processing for calculating the second consumption amount in a predetermined time period will be described using FIG. 3. FIG. 3 is a drawing depicting an example of function data (an example of first correlation data). In FIG. 3, the vertical axis represents the second consumption amount, and the horizontal axis represents room temperature. A function F, for example, is a function that is calculated in advance on the basis of the results of experiments or the like.

First, the second consumption amount calculation unit 302 reads out the function data depicted in FIG. 3 from the storage unit 102. Next, the second consumption amount calculation unit 302 calculates a representative value t for room temperature from a plurality of items of room temperature data acquired in the predetermined time period (0:00 to 0:59, for example). As depicted in FIG. 3, the second consumption amount calculation unit 302 then determines a second consumption amount pc on the basis of the calculated representative value t and the function F.

In this way, the second consumption amount pc from 0:00 to 0:59 is calculated. It should be noted that the second consumption amount pc is calculated in the same manner in time periods other than 0:00 to 0:59.

In the abovementioned description, the function F is calculated in advance on the basis of the results of experiments or the like; however, it should be noted that the function F may be, for example, learned on the basis of first consumption amounts measured in the past and room temperature values detected in the past. Alternatively, for example, the function F may be obtained by the result of the abovementioned learning having been reflected in a function calculated in advance on the basis of the results of experiments or the like. In addition, parameters such as the weather and the season may be reflected in the abovementioned learning.

Hereinabove, an example of processing for calculating the second consumption amount in a predetermined time period has been described. Hereinafter, we will return to the description of FIG. 2.

When the input unit 101 receives a preset operation, the information generation unit 303 creates a table that indicates the association between the room, the device, and the environment sensor designated by that operation, and causes the storage unit 102 to store that table.

Thereafter, when the first consumption amount is measured by the first consumption amount measurement unit 301 and the second consumption amount is calculated by the second consumption amount calculation unit 302 in each time period, the information generation unit 303 registers the first consumption amount and the second consumption amount for each time period in the table.

Here, an example of the table will be described using FIG. 4. FIG. 4 is a drawing depicting an example of the table.

As depicted in FIG. 4, a table 40 includes room information 401, device information 402, environment sensor information 403, time period information 404, first consumption amount information 405, second consumption amount information 406, and representative value information 407.

The room information 401 is information indicating a room designated by a preset operation. In the example of FIG. 4, the room 20 is registered as the room information 401.

The device information 402 is information indicating a device designated by a preset operation. In the example of FIG. 4, the air conditioner 201 is registered as the device information 402.

The environment sensor information 403 is information indicating an environment sensor designated by a preset operation. In the example of FIG. 4, the temperature sensor 202 is registered as the environment sensor information 403.

The time period information 404 is information indicating a predetermined time period. In the example of FIG. 4, time periods of one-hour units are registered for one day as the time period information 404. Here, the time periods are one-hour units; however, the time periods are not restricted thereto and may be 10-minute units, 30-minute units, or the like. Furthermore, the time periods indicated by the time period information 404 may be designated by the resident of the building 10.

The first consumption amount information 405 is information indicating the first consumption amounts measured by the first consumption amount measurement unit 301.

The second consumption amount information 406 is information indicating the second consumption amounts calculated by the second consumption amount calculation unit 302.

In FIG. 4, a second consumption amount of “50” is registered in each of the time period of 21:00 to 21:59, the time period of 22:00 to 22:59, and the time period of 23:00 to 23:59. The second consumption amount of “50” here is, for example, the power amount assumed to be consumed by the air conditioner 201 in order to maintain the room temperature of the room 20 at 28°.

Meanwhile, in FIG. 4, a first consumption amount of “0” is registered in the time period of 21:00 to 21:59, a first consumption amount of “25” is registered in the time period of 22:00 to 22:59, and a first consumption amount of “50” is registered in the time period of 23:00 to 23:59. The first consumption amount of “0” here is, for example, the power amount in the case where the room temperature is maintained at 28° due to the resident of the building 10 performing an action such as opening a window (an example of an action that contributes to energy saving) rather than using the air conditioner 201 or the electric fan. Furthermore, the first consumption amount of “25” is, for example, the power amount in the case where the room temperature is maintained at 28° due to the resident of the building 10 performing an action such as using another device (the electric fan, for example) instead of the air conditioner 201 (an example of an action that contributes to energy saving). Furthermore, the first consumption amount of “50” is, for example, the power amount in the case where the room temperature is maintained at 28° due to the resident of the building 10 performing an action to use the air conditioner 201 (an action to operate the air conditioner 201 with the temperature being set to 28°, for example).

The representative value information 407 is information indicating a representative value of the room temperature. In the example of FIG. 4, “28°” is registered as the representative value information 407. In FIG. 4, the registered representative values are all 28°; however, it should be noted that representative values that are different in each time period may be registered.

Hereinabove, an example of the table has been described. Hereinafter, we will return to the description of FIG. 2.

When the input unit 101 receives an information output instruction operation, the information generation unit 303 reads out the table from the storage unit 102, and calculates differences between second consumption amounts and first consumption amounts on the basis of that table.

For example, a description will be given regarding the case where the information output instruction operation is received at 23:00 and the table 40 depicted in FIG. 4 is read out. In this case, first, the information generation unit 303 calculates a difference for each time period by subtracting the first consumption amount indicated by the first consumption amount information 405 from the second consumption amount indicated by the second consumption amount information 406 in each of the time periods from 0:00 (an example of the time at the start of one day) to 22:59 (an example of the time immediately preceding the time at which the information output instruction operation is received) indicated by the time period information 404. The information generation unit 303 then totals the calculated differences for each time period to thereby calculate a difference from 0:00 to 22:59.

In the case where the difference from 0:00 to 22:59 is a positive value, it is deemed that energy saving has been realized (in other words, an energy saving effect (also referred to as a power usage reduction effect) has been obtained due to an action that contributes to energy saving having been carried out). However, in the case where the difference from 0:00 to 22:59 is a negative value, it is deemed that energy saving has not been realized (in other words, the energy saving effect (also referred to as the power usage reduction effect) has not been obtained due to an action that contributes to energy saving having not been carried out).

The information generation unit 303 generates difference information indicating the calculated difference (the difference from 0:00 to 22:59, for example), and controls the output unit 103 such that this difference information is displayed. The difference information is thereby displayed on the output unit 103 and presented to the resident of the building 10.

It should be noted that the difference information may include information indicating the room, the device, the environment sensor, the time period, or the like as well as the difference.

Hereinabove, the configuration of the information presentation device 100 has been described.

In the example FIG. 1, the information presentation device 100 has a configuration that includes the input unit 101, the storage unit 102, and the output unit 103; however, it should be noted that at least one of the input unit 101, the storage unit 102, and the output unit 103 may be provided outside of the information presentation device 100.

### <Operation of Information Presentation Device>

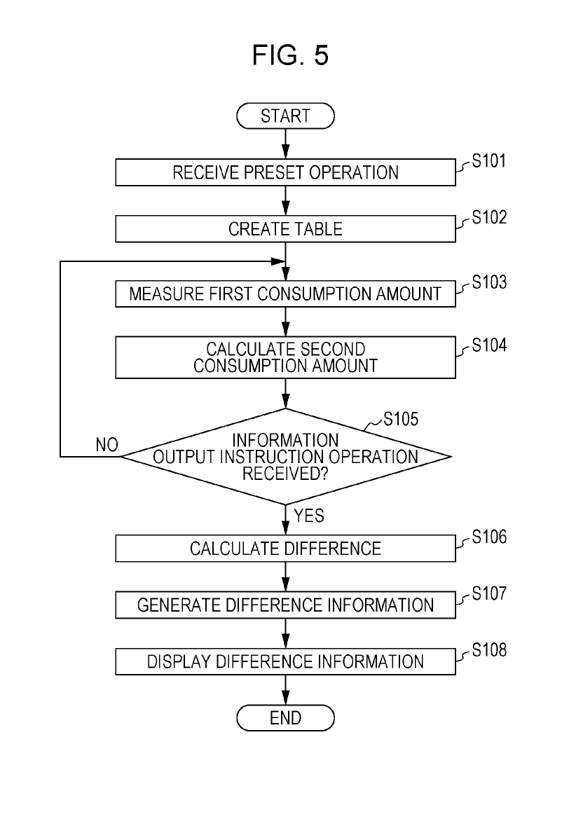

Next, an operation of the information presentation device 100 according to the present embodiment of the present disclosure will be described using FIG. 5. FIG. 5 is a flowchart depicting an example of the flow of an operation (information presentation processing) of the information presentation device 100 according to the embodiment.

First, the input unit 101 receives a preset operation performed by the resident of the building 10 (step S101). The association between the room 20, the air conditioner 201, and the temperature sensor 202 is designated in the preset operation, for example.

Next, the information generation unit 303 of the control unit 104 creates a table indicating the association between the room, the device, and the environment sensor designated by the preset operation, and causes the storage unit 102 to store that table (step S102). For example, the table 40 depicted in FIG. 4 is created. However, at this point in time, the first consumption amount information 405 and the second consumption amount information 406 are not registered in the time periods indicated by the time period information 404.

Next, the first consumption amount measurement unit 301 of the control unit 104 acquires power data indicating the power amount actually consumed by the device installed in the room 20, measures the first consumption amount in each predetermined time period on the basis of the acquired power data, and registers those first consumption amounts in the table (step S103). For example, in the case where the air conditioner 201 and the electric fan (not depicted) are installed in the room 20, the first consumption amount measurement unit 301 measures a first consumption amount on the basis of the power data of the air conditioner 201 and the power data of the electric fan in the each time period, and registers the first consumption amount information 405 indicating the measured first consumption amounts in the table 40 in association with each time period indicated by the time period information 404.

Next, the second consumption amount calculation unit 302 acquires room temperature data indicating a value for the room temperature of the room 20 detected by the temperature sensor 202, and calculates the second consumption amount for each predetermined time period on the basis of the acquired room temperature data and function data (see FIG. 3, for example) read out from the storage unit 102 (step S104). For example, the second consumption amount that is calculated is the power amount assumed to be consumed by the air conditioner 201 in order to maintain the room temperature indicated by the room temperature data. The second consumption amount calculation unit 302 registers the second consumption amount information 406 indicating each second consumption amount calculated in each time period in the table 40, in association with each time period indicated by the time period information 404.

Next, the information generation unit 303 determines whether or not the input unit 101 has received an information output instruction operation (step S105). As mentioned above, the information output instruction operation is, for example, an operation with which the resident of the building 10 instructs difference information to be output. For example, the resident of the building 10 performs the information output instruction operation at a timing at which he or she wishes to confirm the difference information.

In the case where the result of the determination of step S105 indicates that an information output instruction operation has not been received (step S105: no), the flow returns to step S103.

In the case where the result of the determination of step S105 indicates that an information output instruction operation has been received (step S105: yes), the information generation unit 303 calculates the difference between the second consumption amount and the first consumption amount on the basis of the table read out from the storage unit 102 (step S106). As mentioned above, for example, in the case where an information output instruction operation is received at 23:00, the information generation unit 303 calculates the difference from 0:00 to 22:59 on the basis of the table 40 depicted in FIG. 4.

Next, the information generation unit 303 generates difference information indicating the calculated difference (step S107). The information generation unit 303 then controls the output unit 103 such that the generated difference information is displayed. Due to this control, the output unit 103 displays the difference information (step S108). Information indicating the room 20, the air conditioner 201, the temperature sensor 202, the time periods from 0:00 to 22:59, and the like may be displayed as well as the information indicating the difference from 0:00 to 22:59, for example.

In this way, the difference information is presented to the resident of the building 10.

In the above description, it is assumed that processing for calculating the second consumption amount (step S104) is performed after processing for calculating the first consumption amount (step S103); however, it should be noted that such processing may be executed in parallel.

Hereinabove, an operation of the information presentation device 100 has been described.

As described heretofore, according to the present embodiment, a first consumption amount that is the power amount actually consumed by the air conditioner 201 or the like installed in the room 20 of the building 10 is measured, a second consumption amount that is the power amount assumed to be consumed by the air conditioner 201 in order to maintain a room temperature detected in the room 20 is calculated on the basis of the detected room temperature and function data, difference information indicating the difference between the second consumption amount and the first consumption amount is generated, and that difference information is displayed. Thus, according to the present embodiment, it is possible for the difference information (for example, information indicating an energy saving effect (also referred to as a power usage reduction effect) obtained due to the carrying out of an action that contributes to energy saving) to be notified to the resident of the building 10. The resident of the building 10 sees the difference value indicated in the difference information and is able to grasp the extent to which energy saving has been realized.

An embodiment of the present disclosure has been described; however, various modifications of the present embodiment are possible without deviating from the purpose thereof. Hereinafter, modified examples of the present embodiment will be described.

### Modified Example 1

The case where the difference information is output in the output unit 103 of the information presentation device 100 has been described as an example in the abovementioned embodiment; however, there is no restriction thereto. For example, a configuration may be implemented such that a communication unit (not depicted) that performs communication via a predetermined network (the Internet, for example) is provided in the information presentation device 100, and the difference information may be transmitted from that communication unit to a predetermined terminal (a smartphone, a tablet, or the like used by a user). In this case, the difference information is output in the predetermined terminal.

According to the present modified example, the user is able to confirm the difference information even when outside of the building 10.

### Modified Example 2

The case where the difference information is displayed in the output unit 103 of the information presentation device 100 has been described as an example in the abovementioned embodiment; however, there is no restriction thereto. For example, the difference information may be output as audio in the output unit 103. Alternatively, the difference information may be output as audio as well as being displayed in the output unit 103, for example.

According to the present modified example, it becomes even easier for the user to grasp the difference information.

### Modified Example 3

The case where the environment sensor corresponding to the air conditioner 201 is the temperature sensor 202 has been described as an example in the abovementioned embodiment; however, there is no restriction thereto. For example, a humidity sensor that detects humility inside the room 20 may be used instead of the temperature sensor 202.

### Modified Example 4

The case where the device installed in the room 20 is the air conditioner 201 and the environment sensor corresponding thereto is the temperature sensor 202 has been described as an example in the abovementioned embodiment; however, there is no restriction thereto. For example, the device installed in the room 20 may be an illumination device, and the environment sensor corresponding thereto may be an illuminance sensor that detects illuminance inside the room 20. In this case, the second consumption amount is the power amount assumed to be consumed by the illumination device in order to maintain the illuminance detected by the illuminance sensor.

### Modified Example 5

In the abovementioned embodiment, in the case where there are a plurality of rooms in the building 10, the table depicted in FIG. 4 may be created for each room. In this case, difference information of each room is generated on the basis of each table and output. Furthermore, by combining the difference information of each room, difference information of the entire building 10 may be generated and output. Furthermore, the user may be able to designate whether to output difference information of each room or to output difference information of the entire building 10. In addition, in the case where difference information of each room is to be output, the user may be able to designate the rooms for which difference information is to be output.

According to the present modified example, the user is able to confirm the difference information of each room or the difference information of the entire building 10.

### Modified Example 6

In the abovementioned embodiment, for example, in the case where a plurality of different types of devices (the air conditioner 201 and the illumination device, for example) and a plurality of different types of environment sensors (the temperature sensor 202 and the illuminance sensor) are installed in the room 20, difference information of each device (difference information of the air conditioner 201 and difference information of the illumination device) may be generated and output. Furthermore, in the case where difference information of each device is to be output, the user may be able to designate the device for which difference information is to be output. It should be noted that, in this case, the user may designate the device itself, or may designate the environment sensor corresponding to that device (in the case where the environment sensor is designated, the device is specified by means of the association between the device and the environment sensor).

Furthermore, for example, in the case where there are a plurality of rooms in the building 10, and there are a plurality of different types of devices (the air conditioner 201 and the illumination device, for example) and a plurality of different types of environment sensors (the temperature sensor 202 and the illuminance sensor) corresponding to those devices installed in each room, processing such as the following may be performed. Specifically, by combining the difference information of each device, the difference information of all devices of the same type (the air conditioner 201 or the illumination device, for example) installed in the building 10 may be generated and output. Furthermore, the user may be able to designate whether to output the difference information of each device or to output the difference information of all devices of the same type.

According to the present modified example, the user is able to confirm the difference information of each device or the difference information of all devices of the same type installed in the building 10.

### Modified Example 7

The case where the timing of the generation and output of the difference information is when the information output instruction operation is received has been described as an example in the abovementioned embodiment; however, there is no restriction thereto. For example, the difference information may be generated and output at a timing (a time, for example) designated in advance by the user.

According to the present modified example, the user is able to confirm the difference information at a desired timing without performing the information output instruction operation.

### Modified Example 8

The case where the time period in which a difference is to be calculated is 0:00 to 22:59 has been described as an example in the abovementioned embodiment; however, there is no restriction thereto. For example, the time period in which a difference is to be calculated may be a time period designated in advance by the user.

According to the present modified example, the user is able to confirm a difference in a desired time period.

### Modified Example 9

The case where the information presentation device 100 is installed in the building 10 has been described as an example in the abovementioned embodiment; however, there is no restriction thereto. For example, the information presentation device 100 may be a server device arranged in a predetermined network. A configuration example of the information presentation system in this case is depicted in FIG. 6. It should be noted that, in FIG. 6, constituent elements that are the same as those in FIG. 1 are denoted by the same reference numerals, and descriptions thereof are omitted.

As depicted in FIG. 6, compared with the configuration of FIG. 1 described in the embodiment, the information presentation system of the present modified example is different in that the information presentation device 100 is provided with a communication unit 105 and is not provided with the input unit 101 or the output unit 103, and in that the building 10 is provided with a communication device 50 and a display device 60.

The communication device 50, when having received room temperature data from the temperature sensor 202, transmits that room temperature data to the information presentation device 100 via the predetermined network. Furthermore, the communication device 50, when having received power data from the air conditioner 201 via the distribution board 30, transmits that power data to the information presentation device 100 via the predetermined network.

The communication unit 105 of the information presentation device 100 receives the room temperature data and the power data from the communication device 50 and outputs these to the control unit 104. As described in the embodiment, the control unit 104 performs processing to measure the first consumption amount, processing to calculate the second consumption amount, processing to generate difference information, and the like on the basis of the room temperature data and the power data received from the communication unit 105. The control unit 104 then controls the communication unit 105 such that the generated difference information is transmitted to the communication device 50. The communication unit 105 thereby transmits the difference information to the communication device 50 via the predetermined network.

The communication device 50, when having received the difference information transmitted from the communication unit 105, outputs that difference information to the display device 60. The display device 60 displays the difference information received from the communication device 50. The difference information is thereby presented to the resident of the building 10.

According to the present modified example, as in the embodiment, it is possible to notify difference information to the resident of the building 10. The resident of the building 10 sees the difference value indicated in the difference information and is able to grasp the extent to which energy saving has been realized. Furthermore, according to the present modified example, it is not necessary to provide the information presentation device 100 in the building 10, and therefore processing to generate difference information or the like for a plurality of buildings 10 is able to be performed at the same time.

The case where the display device 60 is provided in the building 10 has been described as an example in the present modified example; however, it should be noted that the display device 60 may be a smartphone, a tablet, or the like used by the user, for example.

Furthermore, in the present modified example, the power data of the air conditioner 201 is output to the communication device 50 via the distribution board 30; however, the power data may be output directly to the communication device 50. Alternatively, in the case where the air conditioner 201 is provided with a communication function, the power data of the air conditioner 201 may be transmitted to the information presentation device 100 via a predetermined network without going through the communication device 50.

### Modified Example 10

The case where difference information indicating a calculated difference is output has been described as an example in the abovementioned embodiment; however, information in which the difference is indicated after having been converted into a cost (an amount of money) may be output. For example, the information generation unit 303 reads out correlation data (an example of second correlation data) in which a power amount and a cost have a predetermined correlation from the storage unit 102, and the cost corresponding to the calculated difference in that correlation data is calculated. The information generation unit 303 then generates cost information indicating the calculated cost, and causes the output unit 103 to output that cost information.

According to the present modified example, the user is able to confirm the cost corresponding to a difference.

It should be noted that the cost information may be output instead of the difference information, and may be output together with the difference information.

### Modified Example 11

In the abovementioned embodiment, in addition to the difference information, comment information that indicates a comment corresponding to the difference indicated by that difference information may be output. For example, in the case where the calculated difference is a positive value, the information generation unit 303 generates comment information indicating a comment notifying the achievement of energy saving (“Energy saving has been achieved”, for example), and causes the output unit 103 to output that comment information. However, for example, in the case where the calculated difference is a negative value, the information generation unit 303 generates comment information indicating a comment notifying the non-achievement of energy saving (“Energy saving has not been able to be achieved”, for example), and causes the output unit 103 to output that comment information.

According to the present modified example, the user is able to easily perceive whether or not energy saving has been achieved.

It should be noted that the comment information may be output instead of the difference information. Furthermore, the comment information may be output together with the cost information described in modified example 10.

Furthermore, the content of a comment may be altered according to the magnitude of the difference.

Furthermore, the output form of the comment information is preferably at least one of image display and audio output.

### Modified Example 12

In the abovementioned embodiment, the information generation unit 303 may additionally perform the following operation. For example, first, the information generation unit 303 calculates a difference at predetermined intervals (periodically), and, each time a difference is calculated, determines whether or not that difference has fallen below a predetermined threshold value (zero, for example). The information generation unit 303 then, at the timing at which the difference has fallen below the predetermined threshold value or after a fixed time has elapsed from that timing, generates control information that causes the power amount consumed by the device (the air conditioner 201, for example) to be reduced, and outputs that control information to the device. The power consumption amount of the device (the air conditioner 201, for example) is thereby reduced. The reduction mentioned here includes the power consumption amount being set to zero (the device being turned off).

According to the present modified example, it is possible to suppress wasteful power consumption by causing the power consumption amount of the device to be automatically reduced regardless of user operations in the case where the difference has fallen below the predetermined threshold value.

### Modified Example 13

In the abovementioned embodiment, the information generation unit 303 may additionally perform the following operation. For example, first, the information generation unit 303 calculates a difference at predetermined intervals (periodically), and, each time a difference is calculated, determines whether or not that difference has fallen below a predetermined threshold value (zero, for example). The information generation unit 303 then, at a timing at which the difference has fallen below a predetermined threshold value, creates comment information and causes the output unit 103 to output that comment information.

The comment information here is, for example, information indicating either a comment prompting an action that contributes to energy saving to be carried out, or a comment indicating that energy saving has been achieved up to that point in time. Possible examples of the former comment are “Let's turn off the air conditioner and open a window” and “Let's change the temperature setting” in the case where the device is the air conditioner 201, and “Let's turn off the light” and “Let's decrease the brightness” in the case where the device is an illumination device. Furthermore, a possible example of the latter comment is “Energy saving has been achieved up to now”.

According to the present modified example, the user is able to grasp the timing at which an action that contributes to energy saving should be performed, or is able to easily know that energy saving has been achieved up to that point in time.

Furthermore, the output form of the comment information is preferably at least one of image display and audio output.

### Modified Example 14

In the abovementioned embodiment, the information generation unit 303 may additionally perform the following operation. For example, first, the information generation unit 303 calculates a difference at predetermined intervals (periodically), and, each time a difference is calculated, determines whether or not that difference has fallen below a predetermined first threshold value (zero, for example). Next, in the case where the difference has fallen below the first threshold value, the information generation unit 303 determines whether or not the first consumption amount used to calculate the difference has exceeded a predetermined second threshold value. For example, in the case where the device is the air conditioner 201, the second threshold value is the second consumption amount corresponding to a room temperature that is equal to or greater than the room temperature detected by the temperature sensor 202, in the function data depicted in FIG. 3. Next, in the case where the first consumption amount has exceeded the second consumption amount, the information generation unit 303 generates comment information and causes the output unit 103 to output that common information.

The comment information here is, for example, information indicating a comment prompting maintenance of the device. Possible examples of the comment are “There is a possibility that the device is malfunctioning; please contact the service center” and “Please clean the device”.

According to the present modified example, the user is able to easily know the timing at which maintenance for the device should be performed.

Furthermore, the output form of the comment information is preferably at least one of image display and audio output.

### Modified Example 15

In the abovementioned embodiment, the information generation unit 303 may additionally perform the following operation. Here, the air conditioner 201 and the temperature sensor 202 are described as an example. For example, first, the information generation unit 303 determines whether or not the difference between the room temperature of the room 20 detected by the temperature sensor 202 and the temperature outside of the room 20 (the external air temperature, for example) detected by a sensor other than the temperature sensor 202 has fallen below a predetermined threshold value. Next, in the case where the difference between the room temperature and the outside temperature has fallen below the predetermined threshold value, the information generation unit 303, at a timing at which the air conditioner 201 is operated, generates comment information and causes the output unit 103 to output that comment information.

The common information here is information indicating at least one of a comment indicating that the power amount consumed by the air conditioner 201 is being wasted, and a comment prompting an action that contributes to energy saving to be carried out. A possible example of the former comment is “There is no difference between the room temperature and the external air temperature; power will be wasted if the air conditioner is operated”. Possible examples of the latter comment are comments such as “Let's turn off the air conditioner and open a window” and “Let's turn off the air conditioner and use an electric fan”.

According to the present modified example, the user is able to grasp the timing at which an action that contributes to energy saving should be performed.

Furthermore, the output form of the comment information is preferably at least one of image display and audio output.

Furthermore, although the case where the device is the air conditioner 201 and the environment sensor is the temperature sensor 202 has been described as an example in the abovementioned description, the same is also applicable to the case where the device is an illumination device and the environment sensor is an illuminance sensor. In this case, if the difference between the illuminance inside the room and outside of the room has fallen below a predetermined threshold value, the information generation unit 303 generates comment information indicating at least one of a comment indicating that the power amount consumed by the illumination device is being wasted, and a comment prompting an action that contributes to energy saving (an action that turns off the illumination device to let in natural light, for example) to be carried out.

### Modified Example 16

In the abovementioned embodiment, the information presentation device 100 installed in the building 10 may acquire difference information generated with respect to a section separate from the room 20, via a predetermined network (the Internet, a LAN, or the like), and may output that difference information to the output unit 103 or a terminal device (not depicted) other than the information presentation device 100.

For example, in the case where the building 10 is a detached residence, the abovementioned separate section is the entirety of a detached residence other than the building 10, or a predetermined room (the living room, for example) in that residence.

Furthermore, for example, in the case where the building 10 is a residential complex, the abovementioned separate section is the entirety of one exclusively-owned dwelling other than the one exclusively-owned dwelling that includes the room 20, or a predetermined room (the living room, for example) provided in that one exclusively-owned dwelling.

According to the present modified example, the user is able to refer to difference information in another building or another exclusively-owned single dwelling.

The case where the information presentation device 100 is installed in the building 10 has been described as an example in the present modified example; however, it should be noted that it is also possible for the present modified example to be realized in the information presentation system (see FIG. 6) described in modified example 9. For example, the information presentation device 100 arranged in a predetermined network transmits difference information generated with respect to a building other than the building 10, to the communication device 50 of the building 10. The difference information of the building other than the building 10 is displayed in the display device 60 of the building 10.

### Modified Example 17

In the abovementioned embodiment, the information presentation device 100 (the information generation unit 303, for example) may additionally perform the following operation. For example, first, the information presentation device 100 acquires weather information relating to a weather prediction (weather forecast information, for example) via a predetermined network (the Internet, for example). Next, the information presentation device 100 determines whether or not it is possible for a predetermined environment to be realized without operating the device in the section, on the basis of the acquired weather information. Next, the information presentation device 100 may generate determination result information indicating the result of the determination, and output that determination result information to the output unit 103 or to a terminal device (not depicted) other than the information presentation device 100.

Here, the case where an illumination device and an illuminance sensor are installed in the room 20 will be described in detail as an example with regard to the abovementioned operation.

For example, in the case where the acquired weather information indicates cloudy weather or rainy weather during the daytime, the information presentation device 100 determines that it is not possible to realize a predetermined illuminance (300 lux, for example) unless the illumination device is operated, even if an action to let in natural light (an example of an action that contributes to energy saving) is carried out (in other words, it is necessary to operate the illumination device in order to realize the predetermined illuminance). The information presentation device 100 then, for example, generates determination result information that indicates a comment indicating that it is necessary to use the illumination device, or a comment prompting another means to be used instead of the illumination device.

For example, in the case where the acquired weather information indicates fair weather during the daytime, the information presentation device 100 determines that, due to the action to let in natural light, it is possible to realize the predetermined illuminance (300 lux, for example) without the illumination device being operated (in other words, carrying out the action to let in natural light is sufficient to realize the predetermined illuminance, and therefore it is not necessary to operate the illumination device). The information presentation device 100 then, for example, generates determination result information that indicates a comment indicating that it is not necessary to use the illumination device, or a comment prompting an action to let in natural light to be carried out instead of using the illumination device.

According to the present modified example, the user is able to easily determine whether or not to carry out an action that contributes to energy saving.

### Modified Example 18

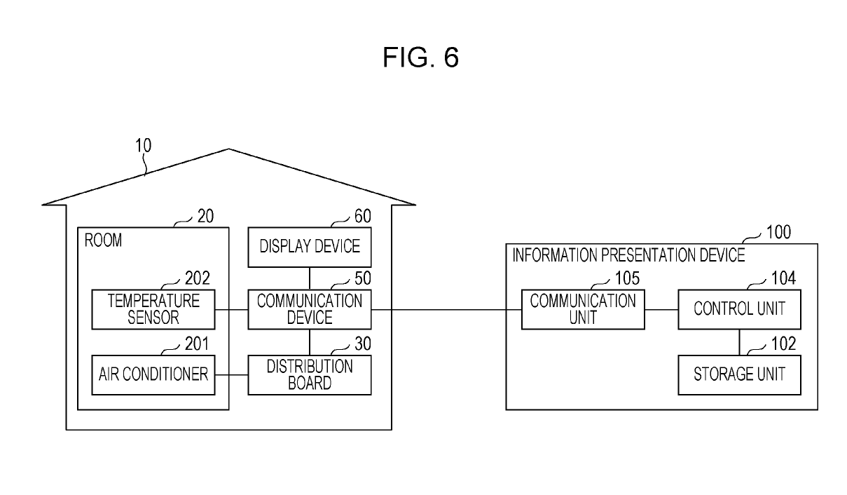

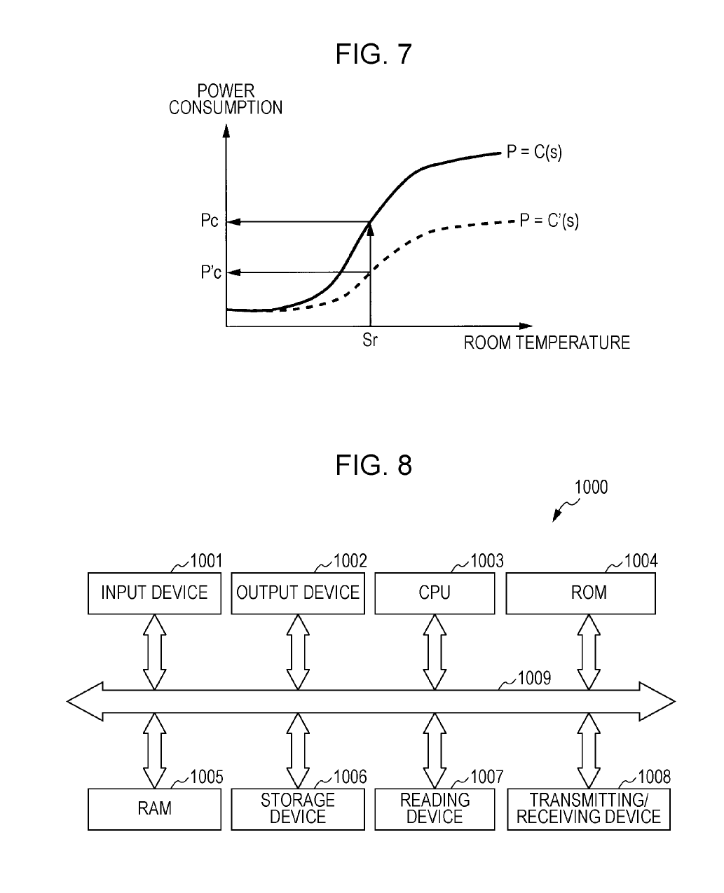

In the abovementioned embodiment, the difference information may additionally include information indicating that an energy saving effect (also referred to as a power usage reduction effect) has been obtained by switching the air conditioner 201 from the current model (the model currently being used by the user) to a new model (a model not currently being used by the user). In this case, for example, the information presentation device 100 (the information generation unit 303, for example) uses the function table depicted in FIG. 7 to calculate a power usage amount by which a reduction can be made due to the model change.

In FIG. 7, the horizontal axis represents room temperature, and the vertical axis represents power consumption. Furthermore, in FIG. 7, P=C(s) is a power consumption function for the current model that is predetermined, and P=C′(s) is a power consumption function for the new model. For example, in the case where the temperature detected by the temperature sensor 202 is Sr, the power consumption Pc of the current model is larger than the power consumption P′c of the new model. In this case, the information presentation device 100 calculates the difference between Pc and P′c, and generates information indicating the calculated value (in other words, the power usage amount by which a reduction can be made due to the model change) in such a way that it is included in the difference information.

According to the present modified example, the user is able to additionally know the power usage amount by which a reduction can be made due to a model change.

Hereinabove, modified examples of the present embodiment have been described. It should be noted that the abovementioned modified examples may be combined in an arbitrary manner.

### (Example of Implementation by Computer Program)

The functions of the information presentation device 100 described in the embodiment and modified examples can be realized by a computer program.

FIG. 8 is a drawing depicting the hardware consideration of a computer that realizes the functions of the information presentation device 100 by means of a program. This computer 1000 is provided with an input device 1001 such as an input button or a touchpad, an output device 1002 such as a display or a speaker, a central processing unit (CPU) 1003, a read-only memory (ROM) 1004, and a random-access memory (RAM) 1005. Furthermore, the computer 1000 is provided with a storage device 1006 such as a hard disk device or a solid-state drive (SSD), a reading device 1007 that reads information from a recording medium such as a digital versatile disc read-only memory (DVD-ROM) or a Universal Serial Bus (USB) memory, and a transmitting/receiving device 1008 that performs communication via a network. The abovementioned units are connected by a bus 1009.

The reading device 1007 reads a program for realizing the functions of the abovementioned units from a recording medium on which the program is recorded, and causes the storage device 1006 to store the program. Alternatively, the transmitting/receiving device 1008 communicates with a server device connected to a network, and causes the storage device 1006 to store a program for realizing the functions of the abovementioned units downloaded from the server device.

The CPU 1003 then copies the program stored in the storage device 1006 to the RAM 1005, and sequentially reads out commands included in the program from the RAM 1005 and executes the commands, thereby realizing the functions of the abovementioned units. Furthermore, when the program is executed, the information obtained by the various processing described in the embodiment and the modified examples is stored in the RAM 1005 and the storage device 1006 and used as appropriate.

### (Cloud Service Models)

Furthermore, the techniques described in the embodiment and the modified examples can be realized in the following cloud service models, for example. However, the models with which the techniques described in the embodiment and the modified examples are realized are not restricted to the following.

(Service Model 1: Type where a Company Itself Serves as a Data Center)

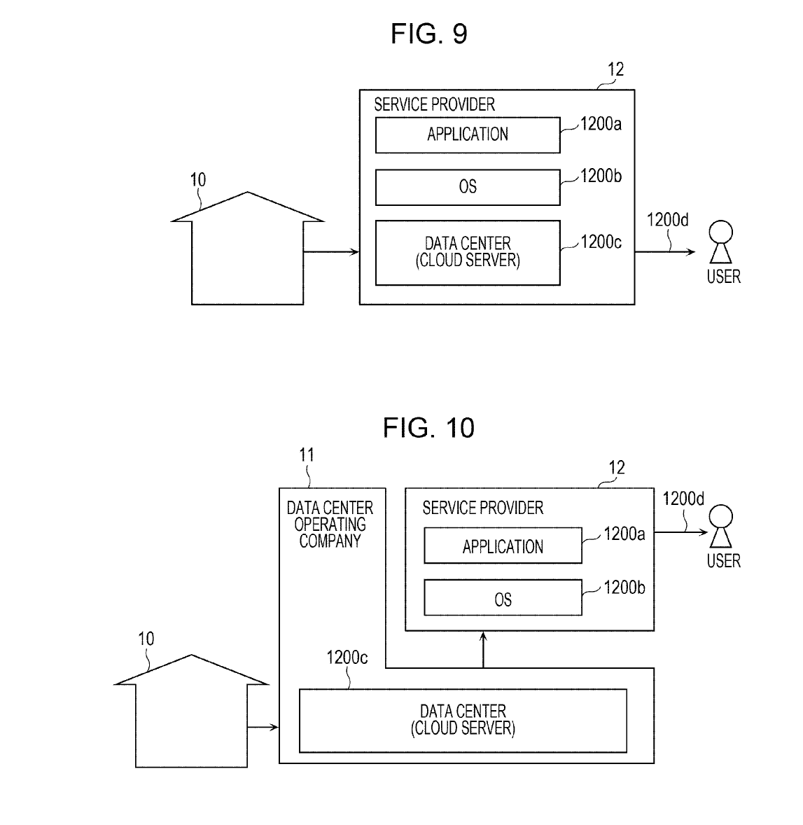

FIG. 9 is a drawing depicting service model 1 (type where a company itself serves as a data center). In the present model, a service provider 12 acquires information from the building 10, and provides a service to users. In the present model, the service provider 12 has the functions of a data center operating company. In other words, the service provider possesses a cloud server (a virtual server that cooperates with various devices via the Internet) that manages big data. Accordingly, a data center operating company is not present.

The abovementioned data center operating company is a company that, for example, manages data, manages the cloud server, and operates a data center that performs said management, but is not restricted thereto. For example, in the case where an equipment manufacturer that develops and manufactures one device from among a plurality of devices used in the building 10 manages data, manages a cloud server, or the like as well as the developing and manufacturing, the equipment manufacturer corresponds to a data center operating company. Furthermore, the data center operating company is not limited to one company. For example, in the case where an equipment manufacturer and another management company are managing data or operating a cloud server on a joint or shared basis, both or either one of the equipment manufacturer and the management company correspond to a data center operating company. It should be noted that the definitions of a data center operating company described here also apply to models 2 to 4 described later on.

In the present model, the service provider 12 operates and manages a data center (cloud server) 1200c. Furthermore, the service provider 12 manages an OS 1200b and an application 1200a. The service provider 12 uses the OS 1200b and the application 1200a managed by the service provider 12 to provide a service to users (1200d).

### (Service Model 2: IaaS-Utilizing Type)

FIG. 10 is a drawing depicting service model 2 (IaaS-utilizing type). IaaS here is an abbreviation for infrastructure as a service, and is a cloud service provision model in which an infrastructure for constructing and running a computer system is itself provided as a service via the Internet.

In the present model, the data center operating company operates and manages the data center (cloud server) 1200c. Furthermore, the service provider 12 manages the OS 1200b and the application 1200a. The service provider 12 uses the OS 1200b and the application 1200a managed by the service provider 12 to provide a service to users (1200d).

### (Service Model 3: PaaS-Utilizing Type)

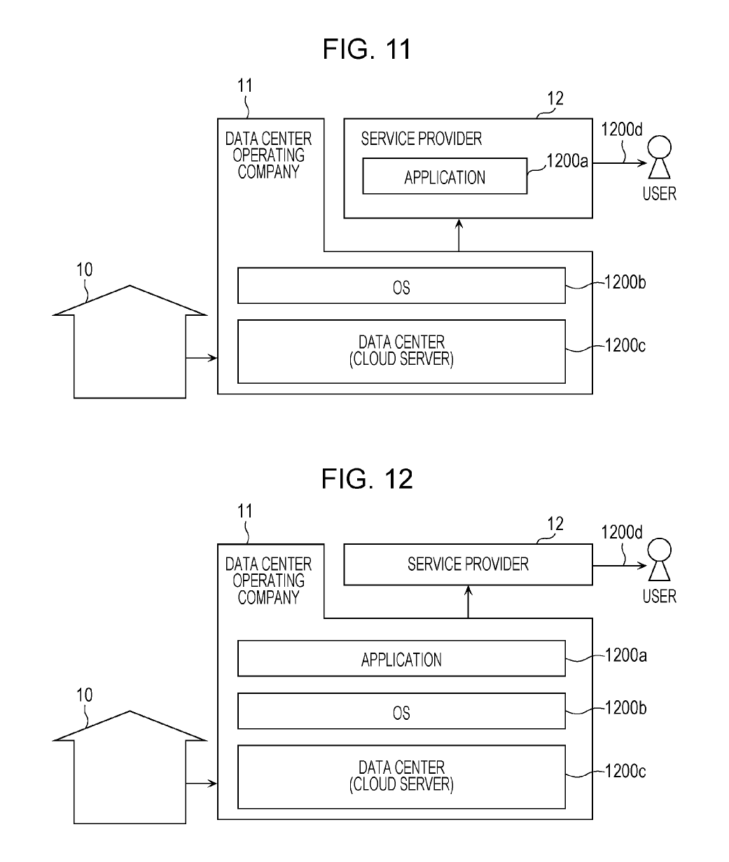

FIG. 11 is a drawing depicting service model 3 (PaaS-utilizing type). PaaS here is an abbreviation for platform as a service, and is a cloud service provision model in which a platform that is a foundation for constructing and running software is provided as a service via the Internet.

In the present model, a data center operating company 11 manages the OS 1200b, and operates and manages the data center (cloud server) 1200c. Furthermore, the service provider 12 manages the application 1200a. The service provider 12 uses the OS 1200b managed by the data center operating company and the application 1200a managed by the service provider 12 to provide a service to users (1200d).

### (Service Model 4: SaaS-Utilizing Type)

FIG. 12 is a drawing depicting service model 4 (SaaS-utilizing type). SaaS here is an abbreviation for software as a service, and is a cloud service provision model that has a function with which it is possible for, for example, a company/individual (user) that does not possess a data center (cloud server) to use an application provided by a platform provider that does possess a data center (cloud server), via a network such as the Internet.

In the present model, the data center operating company 11 manages the application 1200a, manages the OS 1200b, and operates and manages the data center (cloud server) 1200c. Furthermore, the service provider 12 uses the OS 1200b and the application 1200a managed by the data center operating company 11 to provide a service to users (1200d).

The service provider 12 performs a service provision action in all of the above models. Furthermore, for example, the development of an OS, an application, a database for big data, or the like may be implemented by the service provider or the data center operating company itself, or may be outsourced to a third party.

An information presentation method in the present disclosure are not limited to the above embodiments, and have, for example, configurations described in the following items.

### Item 1

An information presentation method comprising:

measuring a first consumption amount that is an amount of the energy actually consumed by a device installed in a section in a building;

calculating a second consumption amount that is an amount of the energy assumed to be consumed by the device in order to maintain an environment value that indicates an environment of the section;

generating difference information indicating a difference between the second consumption amount and the first consumption amount;

outputting the difference information to a terminal; and

causing the terminal to present the difference information.

### Item 2

The information presentation method according to item 1, further comprising:

acquiring first correlation data in which the environment value and the second consumption amount have a predetermined correlation;

acquiring the environment value from an environment sensor that detects the environment value in the section;

determining the second consumption amount corresponding to the environment value acquired from the environment sensor in the first correlation data; and

generating the difference information indicating the difference between the determined second consumption amount and the first consumption amount.

### Item 3

The information presentation method according to item 2,

wherein the first correlation data is data that has been learned based on the first consumption amount measured in the past and the environment value detected in the past.

### Item 4

The information presentation method according to item 2,

wherein an association between the section, the device, and the environment sensor is designated in advance by a user.

### Item 5

The information presentation method according to item 4,

wherein, in a case where the building is provided with a plurality of sections, the section is designated by the user,

and the difference information is generated based on the first consumption amount and the second consumption amount relating to the device associated with the section designated by the user.

### Item 6

The information presentation method according to item 4,

wherein, in a case where, in the section, different types of the device are installed in plurality and different types of the environment sensor are installed in plurality, the device is designated by the user,

and the difference information is generated based on the first consumption amount and the second consumption amount relating to the device designated by the user.

### Item 7

The information presentation method according to item 4,

wherein, in a case where, in the section, different types of the device are installed in plurality and different types of the environment sensor are installed in plurality, the environment sensor is designated by the user,

and the difference information is generated based on the first consumption amount and the second consumption amount relating to the device associated with the environment sensor designated by the user.

### Item 8

The information presentation method according to item 1,

wherein the first consumption amount and the second consumption amount are associated in each predetermined period and stored in a predetermined storage device,

the first consumption amount and the second consumption amount are read out from the predetermined storage device at a predetermined timing, and the difference information is generated based on the first consumption amount and the second consumption amount.

### Item 9

The information presentation method according to item 2,

wherein the environment sensor is an illuminance sensor,

the environment value is a value indicating an illuminance of the section detected by the illuminance sensor,

and the device is an illumination device.

### Item 10

The information presentation method according to item 2,

wherein the environment sensor is a temperature sensor,

the environment value is a value indicating a temperature of the section detected by the temperature sensor,

and the device is an air conditioner.

### Item 11

The information presentation method according to item 1,

wherein a cost corresponding to the calculated difference is calculated based on second correlation data in which an amount of the energy and the cost have a predetermined correlation,

cost information indicating the calculated cost is generated, and the cost information is output to the predetermined terminal.

### Item 12

The information presentation method according to item 1,

wherein, in addition to the difference information, comment information indicating a comment corresponding to the difference indicated by the difference information is output to the predetermined terminal.

### Item 13

The information presentation method according to item 1,

wherein the difference is calculated at predetermined intervals, whether or not the difference has fallen below a predetermined threshold value is determined each time the difference is calculated,

and control that causes the amount of the energy consumed by the device to be reduced is performed at a timing at which the difference has fallen below the threshold value, or after a fixed time has elapsed from the timing.

### Item 14

The information presentation method according to item 1,

wherein the difference is calculated at predetermined intervals, whether or not the difference has fallen below a predetermined threshold value is determined each time the difference is calculated,

and comment information either prompting an action that contributes to energy saving to be carried out or indicating that energy saving has been achieved up to that point in time is output to the predetermined terminal at a timing at which the difference has fallen below the threshold value.

### Item 15

The information presentation method according to item 1,

wherein the difference is calculated at predetermined intervals, whether or not the difference has fallen below a predetermined first threshold value is determined each time the difference is calculated,

in a case where the difference has fallen below the first threshold value, whether or not the first consumption amount used to calculate the difference has exceeded a predetermined second threshold value is determined,

and in a case where the first consumption amount has exceeded the second threshold value, comment information prompting maintenance of the device is output to the predetermined terminal.

### Item 16

The information presentation method according to item 1,

wherein, in a case where a difference between the environment value indicating the environment inside the section detected by the environment sensor and a separately detected external environment value indicating an environment outside of the section has fallen below a predetermined threshold value, comment information indicating at least one of that the energy consumed by the device is being wasted and that an action contributing to energy saving should be carried out is output to the predetermined terminal at a timing at which the device is operated.

### Item 17

The information presentation method according to item 14,

wherein at least one of the difference information and the comment information is output by at least one of screen display and audio in the predetermined terminal.

### Item 18

The information presentation method according to item 1,

wherein the difference information generated with respect to a section separate from the predetermined section is acquired, and the difference information is output to the predetermined terminal.

### Item 19

The information presentation method according to item 1,

wherein weather information relating to a weather prediction is acquired,

whether or not it is possible for a predetermined environment to be realized without operating the device in the section is determined based on the weather information, and

determination result information indicating a result of the determination is output to the predetermined terminal.

### Item 20

The information presentation method according to item 8,

wherein the predetermined period is designated by a user.

### Item 21

An information presentation device comprising:

one or more memories; and circuitry operative to:

measure a first consumption amount that is an amount of the energy actually consumed by a device installed in a section in a building;

calculate a second consumption amount that is an amount of the energy assumed to be consumed by the device in order to maintain an environment value that indicates an environment of the section;

generate difference information indicating a difference between the second consumption amount and the first consumption amount;

output the difference information to a terminal; and

cause the terminal to present the difference information.

The present disclosure is suitable for an information presentation method and an information presentation device with which information relating to energy consumption is presented.

What is claimed is:

1. An information presentation method comprising:
measuring a first consumption amount that is an amount of the energy actually consumed by a device installed in a section in a building;
calculating a second consumption amount that is an amount of the energy assumed to be consumed by the device in order to maintain an environment value that indicates an environment of the section;
generating difference information indicating a difference between the second consumption amount and the first consumption amount;
outputting the difference information to a terminal; and
causing the terminal to present the difference information.

2. The information presentation method according to claim 1, further comprising:
acquiring first correlation data in which the environment value and the second consumption amount have a predetermined correlation;
acquiring the environment value from an environment sensor that detects the environment value in the section;
determining the second consumption amount corresponding to the environment value acquired from the environment sensor in the first correlation data; and
generating the difference information indicating the difference between the determined second consumption amount and the first consumption amount.

3. The information presentation method according to claim 2,
wherein the first correlation data is data that has been learned based on the first consumption amount measured in the past and the environment value detected in the past.

4. The information presentation method according to claim 2,
wherein an association between the section, the device, and the environment sensor is designated in advance by a user.

5. The information presentation method according to claim 4,
wherein, in a case where the building is provided with a plurality of sections, the section is designated by the user,
and the difference information is generated based on the first consumption amount and the second consumption amount relating to the device associated with the section designated by the user.

6. The information presentation method according to claim 4,
wherein, in a case where, in the section, different types of the device are installed in plurality and different types of the environment sensor are installed in plurality, the device is designated by the user,
and the difference information is generated based on the first consumption amount and the second consumption amount relating to the device designated by the user.

7. The information presentation method according to claim 4,
wherein, in a case where, in the section, different types of the device are installed in plurality and different types of the environment sensor are installed in plurality, the environment sensor is designated by the user,
and the difference information is generated based on the first consumption amount and the second consumption amount relating to the device associated with the environment sensor designated by the user.

8. The information presentation method according to claim 1,
wherein the first consumption amount and the second consumption amount are associated in each predetermined period and stored in a predetermined storage device,
the first consumption amount and the second consumption amount are read out from the predetermined storage device at a predetermined timing, and the difference information is generated based on the first consumption amount and the second consumption amount.

9. The information presentation method according to claim 2,
wherein the environment sensor is an illuminance sensor,
the environment value is a value indicating an illuminance of the section detected by the illuminance sensor,
and the device is an illumination device.

10. The information presentation method according to claim 2,
wherein the environment sensor is a temperature sensor,
the environment value is a value indicating a temperature of the section detected by the temperature sensor,
and the device is an air conditioner.

11. The information presentation method according to claim 1,
wherein a cost corresponding to the calculated difference is calculated based on second correlation data in which an amount of the energy and the cost have a predetermined correlation,
cost information indicating the calculated cost is generated, and the cost information is output to the predetermined terminal.

12. The information presentation method according to claim 1,
wherein, in addition to the difference information, comment information indicating a comment corresponding to the difference indicated by the difference information is output to the predetermined terminal.

13. The information presentation method according to claim 1,
wherein the difference is calculated at predetermined intervals, whether or not the difference has fallen below a predetermined threshold value is determined each time the difference is calculated,
and control that causes the amount of the energy consumed by the device to be reduced is performed at a timing at which the difference has fallen below the threshold value, or after a fixed time has elapsed from the timing.

14. The information presentation method according to claim 1,
wherein the difference is calculated at predetermined intervals, whether or not the difference has fallen below a predetermined threshold value is determined each time the difference is calculated,
and comment information either prompting an action that contributes to energy saving to be carried out or indicating that energy saving has been achieved up to that point in time is output to the predetermined terminal at a timing at which the difference has fallen below the threshold value.

15. The information presentation method according to claim 1,
wherein the difference is calculated at predetermined intervals, whether or not the difference has fallen below a predetermined first threshold value is determined each time the difference is calculated,
in a case where the difference has fallen below the first threshold value, whether or not the first consumption amount used to calculate the difference has exceeded a predetermined second threshold value is determined,
and in a case where the first consumption amount has exceeded the second threshold value, comment information prompting maintenance of the device is output to the predetermined terminal.

16. The information presentation method according to claim 1,
wherein, in a case where a difference between the environment value indicating the environment inside the section detected by the environment sensor and a separately detected external environment value indicating an environment outside of the section has fallen below a predetermined threshold value, comment information indicating at least one of that the energy consumed by the device is being wasted and that an action contributing to energy saving should be carried out is output to the predetermined terminal at a timing at which the device is operated.

17. The information presentation method according to claim 14,
wherein at least one of the difference information and the comment information is output by at least one of screen display and audio in the predetermined terminal.

18. The information presentation method according to claim 1,
wherein the difference information generated with respect to a section separate from the predetermined section is acquired, and the difference information is output to the predetermined terminal.

19. The information presentation method according to claim 1,
wherein weather information relating to a weather prediction is acquired,
whether or not it is possible for a predetermined environment to be realized without operating the device in the section is determined based on the weather information, and
determination result information indicating a result of the determination is output to the predetermined terminal.

20. An information presentation device comprising:
one or more memories; and circuitry operative to:
measure a first consumption amount that is an amount of the energy actually consumed by a device installed in a section in a building;
calculate a second consumption amount that is an amount of the energy assumed to be consumed by the device in order to maintain an environment value that indicates an environment of the section;
generate difference information indicating a difference between the second consumption amount and the first consumption amount;
output the difference information to a terminal; and
cause the terminal to present the difference information.
